(19) United States
(12) Patent Application Publication
(10) Pub. No.: US 2014/0124788 A1
(43) Pub. Date: May 8, 2014

(54) Chemical Vapor Deposition System

(71) Applicant: INTERMOLECULAR, INC., San Jose, CA (US)

(72) Inventors: Philip Kraus, San Jose, CA (US); Boris Borisov, Edina, MN (US); Thai Cheng Chua, Cupertino, CA (US); Sandeep Nijhawan, Los Altos, CA (US)

(73) Assignee: INTERMOLECULAR, INC., San Jose, CA (US)

(21) Appl. No.: 13/670,269

(22) Filed: Nov. 6, 2012

(51) Int. Cl. H01L 21/205; H01L 29/205; H01L 33/32

(52) U.S. Cl. 257/76; 118/719; 118/702; 438/478; 257/E21.108; 257/E29.091

(57) ABSTRACT

Chemical vapor deposition (CVD) systems for forming layers on a substrate are disclosed. Embodiments of the system comprise at least two processing chambers that may be linked in a cluster tool. A first processing chamber provides a chamber having a controlled environmental temperature and pressure and containing a first environment for performing CVD on a substrate, and a second environment for contacting the substrate with a plasma; a substrate transport system capable of positioning a substrate for sequential processing in each environment, and a gas control system capable of maintaining isolation. A second processing chamber provides a CVD system. Methods of forming layers on a substrate comprise forming one or more layers in each processing chamber. The systems and methods are suitable for preparing Group III-V, Group II-VI or Group IV thin film devices.

### CROSS REFERENCE TO RELATED APPLICATIONS

This application is related to commonly owned U.S. patent application Ser. No. 13/546,672 and commonly owned U.S. patent application Ser. No. 13/025,046 now U.S. Pat. No. 8,143,147, which are herein incorporated by reference. This application is also related to commonly owned co-pending U.S. patent application Ser. No. 13/398,663 (filed on Feb. 16, 2012) and Ser. No. 13/398,988 (filed on Feb. 17, 2012) which claim the benefit of Ser. No. 13/025,046, which are herein incorporated by reference.

### FIELD OF THE INVENTION

One or more embodiments of the present invention relate to methods and apparatuses for practicing chemical vapor deposition.

### BACKGROUND

The growth of high-quality crystalline semiconducting thin films is a technology of significant industrial importance, with a variety of microelectronic and optoelectronic applications, including light emitting diodes and lasers. The state of the art technique for the construction of optoelectronic devices comprising layers of semiconducting materials is metal organic chemical vapor deposition (MOCVD), in which a substrate is held at high temperature and gases which contain the elements comprising the thin film flow over and are incorporated into the growing thin film at the surface of the wafer. This technology is particularly useful for forming thin films of, for example, gallium nitride (GaN), indium nitride (InN) and aluminum nitride (AlN), their alloys and their heterostructures; hereafter these are referred to as InGaAlN thin films. In the case of GaN, the state-of-the-art may include growth temperatures of approximately 1050° C. and the simultaneous use of ammonia (NH₃) and a Group III alkyl precursor gas (e.g., trimethylgallium, triethylgallium).

The growth of GaN on Si substrates is a technique under development by the LED industry and the power electronics industry for improved economy. Si substrates are available in larger diameters that can be processed in bigger machines for larger scale manufacturing. However, the deposition of GaN on Si substrates is complicated by the need for an adequate buffer layer between the Si substrate and the GaN. The buffer layer is needed because free Ga present on the Si surface during the initial stages of GaN growth directly on Si results in undesirable etch pits in the Si substrate. Additionally, there is a poor lattice match between GaN and Si that results in large and undesirable lattice strain in deposited GaN layers. AlN is a candidate buffer layer due to its lack of chemical reactivity with Si and despite its slightly worse epitaxial compatibility (lattice match) with GaN. However, the high processing temperature necessary to deposit AlN layers, typically 1200° C. or greater to form c-axis oriented AlN, makes AlN deposition challenging. An alternative, low-temperature deposition method for AlN on Si would be an improvement on the state of the art.

While methods exist for forming InGaAlN films, there are limitations associated with current methods. First, the high processing temperature involved in MOCVD may require complex reactor designs and the use of refractory materials and only materials which are inert at the high temperature of the process in the processing volume. Second, the high temperature involved may restrict the possible substrates for InGaAlN growths to substrates which are chemically and mechanically stable at the growth temperatures and chemical environment, typically sapphire and silicon carbide substrates. Notably, silicon substrates, which are less expensive and are available in large sizes for economic manufacturing, may be less compatible. Third, the expense of the process gases involved as well as their poor consumption ratio, particularly in the case of ammonia, may be economically unfavorable for low cost manufacturing of InGaAlN based devices. Fourth, the use of carbon containing precursors (e.g., trimethylgallium) may result in carbon contamination in the InGaAlN film, which may degrade the electronic and optoelectronic properties of the InGaAlN based devices. Fifth, MOCVD reactors may result in a significant amount of gas phase reactions between the Group III and the Group V containing process gases, leading to the undesirable deposition of the thin film material on all surfaces within the reaction volume, and in the undesirable generation of particles, as well as inefficient loss of reactants. The latter may result in a low yield of manufactured devices. The former may result in a number of practical problems, including reducing the efficacy of in situ optical measurements of the growing thin film due to coating of the internal optical probes and lens systems, and difficulty in maintaining a constant thermal environment over many deposition cycles as the emissivity of reactor walls will change as deposition builds up on the reactor walls. These problems may be common to all the variants of MOCVD, including plasma enhanced MOCVD and processes typically referred to as atomic layer deposition (ALD) or atomic layer epitaxy (ALE).

Other methods for forming InGaAlN thin films include plasma-assisted molecular beam epitaxy (“PAMBE”), in which fluxes of evaporated Ga, In, or Al are directed in high vacuum at a heated substrate simultaneously with a flux of nitrogen radicals (either activated molecular nitrogen, atomic nitrogen, or singly ionized nitrogen atoms or molecules) from a nitrogen plasma source. The method may be capable of producing high quality InGaAlN thin films and devices, but the method may suffer from a tendency to form metal agglomerations, e.g., nano- to microscopic Ga droplets, on the surface of the growing film. See, for example, “Homoepitaxial growth of GaN under Ga-stable and N-stable conditions by plasma-assisted molecular beam epitaxy”, E. J. Tarsa et al., J. Appl. Phys 82, 11 (1997), which is entirely incorporated herein by reference. As such, the process may need to be carefully monitored, which may inherently result in a low yield of manufactured devices.

Other methods employed to make GaN films include hydride vapor phase epitaxy, in which a flow of HCl gas over heated gallium results in the transport of gallium chloride to a substrate where simultaneous exposure to ammonia results in the growth of a GaN thin film. The method may require corrosive chemicals to be used at high temperatures, which may limit the compatible materials for reactor design. In addition, the byproducts of the reaction are corrosive gases and solids, which may increase the need for abatement and reactor maintenance. While the method may produce high quality GaN films at growth rates (tens to hundreds of microns per hour have been demonstrated, exceeding those commonly achieved with MOCVD), the reactor design and corrosive process inputs and outputs are drawbacks.

Plasma enhanced chemical vapor deposition (PECVD) is also in wide use in the semiconductor industry for a variety of materials used in processing for integrated circuits. PECVD suffers from excessive gas phase reactions and dust generation due to the interaction of the charged species in the plasma with the precursors for the deposition. It is not currently accepted as a manufacturing solution for LEDs for white lighting applications or for power electronics. However, it is suitable for use in the photovoltaics industry, for example in amorphous silicon deposition.

U.S. Pat. No. 6,652,924 to Sherman describes sequential chemical vapor deposition by employing a reactor operated at low pressure, a pump to remove excess reactants and a line to introduce gas into the reactor through a valve. A first reactant forms a monolayer on the part to be coated, while the second reactant passes through a radical generator which activates the second reactant into a gaseous radical making it available to react with the monolayer. A pump removes the excess second reactant and reaction products to complete the process cycle, which can be repeated to grow a desired thickness of film. However, the process is time consuming and inefficient since the chamber must be evacuated between each reaction cycle.

Atomic layer deposition (ALD) is another implementation of chemical vapor deposition, and utilizes specific reaction conditions and pathways to provide self limiting surface coverage of only a single atomic layer per cycle. For example, U.S. Patent Application Publication No. 2007/0218702 to Shimizu et al. describes an apparatus for depositing a thin film on a processing target that includes: a reaction space; a susceptor movable up and down and rotatable around its center axis; and isolation walls that divide the reaction space into multiple compartments including source gas compartments and purge gas compartments. When the susceptor is raised for film deposition, a small gap is reportedly created between the susceptor and the isolation walls, thereby establishing gaseous separation between the respective compartments. Each source gas compartment and each purge gas compartment are provided alternately in a susceptor-rotating direction of the susceptor. The process may include use of a plasma chamber in which RF plasma is generated continuously, in order to deposit a film using plasma enhanced atomic layer deposition without a need for intermittent on/off operations of RF. However, the described process limits coverage to one monolayer per exposure and use of purge gas compartments to separate the source gas compartments and plasma chamber.

### SUMMARY OF THE INVENTION

Deposition systems and methods for forming layers on a substrate are disclosed using the systems. Embodiments of the deposition system comprise a first substrate transport system capable of loading substrates sequentially into a plurality of processing chambers. A first processing chamber is operable to form a layer by contacting the substrate with one or more precursor gases (i.e., by chemical vapor deposition [CVD]) and to contact the substrate (or a layer deposited on the substrate) with a plasma. The first processing chamber, a combined CVD/plasma chamber, comprises a first processing environment, a second processing environment, a second substrate transport system capable of positioning a substrate for sequential processing in each environment, and a gas control system capable of maintaining isolation of each environment. The first processing environment comprises a system operable to contact the substrate with a plurality of precursor gases, such as metalorganic precursors, for forming layers on the substrate, and the second processing environment comprises a system for contacting the substrate with a plasma. Embodiments of the first processing chamber are described in detail in U.S. Pat. No. 8,143,147 and U.S. patent application Ser. No. 13/546,672, both of which are incorporated by reference herein.

The second substrate transport system can be a planetary wafer transport system comprising one or more substrate supports disposed on a motorized platform rotating about a central axis disposed approximately equidistant from each processing environment, and a controller for controlling the time spent in each processing environment and the speed at which the substrate moves between processing environments. The one or more substrate supports are capable of independently controlling the temperature of the substrate. The substrate supports can further comprise a motor for providing rotational motion to the substrates. A substrate support can further comprise a heater.

The gas control system of the first processing chamber provides for the introduction and evacuation of gases such that gases from one processing environment are not reactive in another processing environment, thereby providing isolation between the processing environments. The gas control system also comprises a plurality of mass flow controllers for maintaining a predetermined pressure, flow rate and gas composition in the environments.

The first processing chamber can also comprise additional chemical deposition or plasma environments as needed for performing desired processing steps. In some embodiments, the first processing chamber comprises at least two processing environments operable to form a layer by contacting the substrate with a plurality of precursor gases. In some embodiments, the system comprises at least two processing environments operable to contact the substrate with a plasma. The first processing chamber can further comprise a metrology environment for monitoring deposition rate, thickness, composition and the like.

A second processing chamber is operable to deposit one or more layers on the substrate by reaction of precursor gases on the substrate (i.e., by CVD). CVD methods can include metal organic chemical vapor deposition (MOCVD). The second (e.g., CVD) processing chamber comprises a gas emission system capable of providing a plurality of precursor gases for deposition onto a substrate, where the precursors are delivered to the substrate in the same environment and at the same time. The processing chamber is operable to deposit one or more layers on the substrate by reaction of precursor gases on the substrate.

The deposition system can further comprise additional processing chambers, either of the first type or the second, as needed.

In some embodiments, methods of depositing layers on a substrate are provided. The method comprises depositing at least one layer on a substrate by a first method in a first processing chamber, and depositing at least one layer by a second method in a second processing chamber. The first method comprises forming a first layer on a substrate in a first processing environment operable to form a layer by contacting the substrate with a plurality of precursor gases, and contacting the substrate (or a layer formed on the substrate) with plasma in a second processing environment (a plasma environment). The forming and contacting steps can be performed in the first processing chamber which comprises a first processing environment operable to form a layer by contacting the substrate with one or more precursor gases, and a second processing environment for contacting the substrate with a plasma; a substrate transport system capable of positioning the substrate for sequential processing in each environment, and a gas control system capable of maintaining isolation of each environment. The forming and contacting steps can be repeated until layers of desired composition and thickness are formed.

The second method of depositing at least one layer comprises forming a layer from one or more precursors on a substrate in the second processing chamber which is operable to perform CVD, where the precursors are delivered to the substrate in the same environment and at the same time; i.e., the second processing chamber provides a chemical vapor deposition environment. The precursor gases can be provided in any desired molar ratio.

There is no presumed order to the formation of layers in the first or second processing chambers nor is there any presumed order in the use of any chambers or the number of layers produced sequentially in one chamber. For example, the layer formed by the second method in the second processing chamber, i.e., using only chemical vapor deposition, can be formed either before or after a layer is formed by the first method in the first processing chamber. Similarly, processing can start with either chamber, and any number of layers can be formed in any chamber followed by formation of any number of layers in any other chamber, and the substrate can be moved from one chamber to any other chamber as many times as needed to build a particular combination of layers.

In addition, the substrate or a layer on the substrate can be treated with a plasma either before or after a layer is formed thereon by any available deposition method. In some embodiments, contacting the substrate with plasma in the second processing environment can be effective to deposit atoms or molecules from the plasma onto the substrate. In some embodiments, contacting the substrate with plasma in the second processing environment is effective to treat the surface of the substrate or a layer disposed on the substrate. Treatment with a plasma can be effective to enhance adsorbed atom (adatom) migration on the layer, lower the temperature required for growth of the layer, reduce contaminants in the layer, or combinations thereof.

Additional layers can be formed using either the first method or the second method. Precursors typically include Group II, Group III, Group IV, Group V and/or Group IV precursors. The methods can be performed to form devices having multiple distinct layers, such as Group III-V or Group II-VI thin film devices. The methods can be performed to produce layers comprised of Group IV atoms. In some embodiments, the first processing chamber can be used to form one or more “seed” layers or “barrier” layers, and then the CVD chamber can be used to deposit a plurality of device layers.

In some embodiments, the plasma is a reactive plasma comprising one or more of a halogen, oxygen, water, nitrogen, hydrogen, ammonia, hydrazine, methane, ethane, hydrogen chloride. In some embodiments, the plasma is an inert plasma comprising one or more of argon, krypton, helium, neon, or xenon. In some embodiments, the plasma is a neutrals plasma.

In some embodiments, the first method is practiced utilizing a first processing chamber comprising at least two processing environments for performing chemical vapor deposition on the substrate, where the processing environments can be the same or different. In some embodiments, the first method is practiced utilizing a first processing chamber comprising at least two processing environments for contacting the substrate with a plasma, where the processing environments can be the same or different.

In some embodiments, the methods can be performed to prepare a Group III-V, Group II-VI, or Group IV thin film device. In some embodiments, the methods can be performed to prepare a light emitting diode (LED) having a Group III-V thin film. The LED can comprise a substrate such as silicon, and additional layers such as an AlN layer, a GaN layer, or an AlGaN layer.

### BRIEF DESCRIPTION OF THE DRAWINGS

FIG. 1 shows a schematic illustration of a cluster tool.

FIG. 2 shows a schematic of one embodiment of a chemical vapor deposition system according to the present invention.

FIG. 3 shows an optical emission spectrum of a radio-frequency inductively coupled plasma excitation of N₂ gas.

### DETAILED DESCRIPTION

Before the present invention is described in detail, it is to be understood that unless otherwise indicated this invention is not limited to specific layer compositions. Exemplary embodiments will be described for materials produced for LED applications, but monolayers, bilayers and multilayers comprising Group III-V films, Group IV films, Group II-VI films and the like can beneficially be produced using the methods disclosed herein. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention.

### DEFINITIONS

The term “environment,” as used herein refers to regions in a deposition system that are suitable for deposition of a layer using CVD on or over a substrate or group of substrates, treatment of a substrate or a layer on a substrate with a plasma, or the measurement of the physical characteristics of the layers on a substrate. In some embodiments, an environment includes a chamber. In some embodiments, an environment can include a chamber in a system having a plurality of chambers. In some embodiments, an environment can include a chamber in a system having a plurality of fluidically separated chambers. In some embodiments, a system can include multiple environments, wherein each environment is isolated from another environment. In some embodiments, an environment can be suitable for conducting measurements on a substrate or a layer formed on the substrate.

The term “metal nitride,” as used herein, refers to a material comprising one or more metals and nitrogen or one or more semiconductors and nitrogen. In some embodiments, a metal nitride (e.g., metal nitride thin film) can have the chemical formula MeₓN_{y}, wherein ‘Me’ designates a metal or a semiconductor, ‘N’ designates nitrogen, and x and y are numbers greater than zero. In some embodiments, ‘Me’ can comprise one or more metals and/or semiconductors. In some embodiments, MeₓN_{y} refers to a metal nitride, such as a Group III metal nitride (e.g., gallium nitride, indium nitride, aluminum gallium nitride, indium gallium aluminum nitride). In some embodiments, a metal nitride film or thin film can comprise other materials, such as, e.g., chemical dopants. Chemical dopants can include p-type dopants (e.g., magnesium, zinc) and n-type dopants (e.g., silicon, oxygen).

The terms “excited species” and “activated species,” as used herein, refer to radicals, ions and other excited (or activated) species generated via application (or coupling) of energy to a reactant gas or vapor.

The term “neutrals plasma” refers to a plasma which provides a density of excited neutral species at the surface of the substrate while providing negligible ion density at the surface of the substrate. Neutrals plasmas include in particular plasmas comprising hydrogen, oxygen, nitrogen and inert gases.

The term “reactive plasma” refers to a plasma providing reactive radicals and ions that become incorporated into a layer. A reactive plasma can comprise a neutrals plasma.

The terms “nitrogen-containing species,” as used herein, can include, without limitation, nitrogen radicals, nitrogen ions, and excited (or active) neutral species of nitrogen. In some embodiments, the gaseous source of nitrogen-containing species may include, without limitation, N₂, NH₃, and/or hydrazine. In some embodiments, the gaseous source of nitrogen-containing species can include mixtures of N₂ and H₂ gases. In some embodiments, excited nitrogen-containing species or nitrogen plasma can be provided via remote plasma generation or direct plasma generation. In some embodiments, excited nitrogen-containing species can be provided by the thermal disassociation of nitrogen-containing species by exposure to hot surfaces or wires. In some embodiments, coupling energy to a mixture of N₂ and H₂ gases can generate excited molecular NHₓ, wherein x is a number greater than or equal to 1

The term “hydrogen-containing species”, as used herein, can include, without limitation, hydrogen radicals, hydrogen ions, and excited (or active) neutral species of hydrogen (H₂). In some embodiments, a hydrogen plasma includes H₂. In some embodiments, the gaseous source of hydrogen-containing species can include, without limitation, H₂, NH₃, and/or hydrazine. In some embodiments, the gaseous source of hydrogen plasma can include mixtures of H₂ and N₂ gases. In some embodiments, excited hydrogen-containing species or hydrogen plasma can be provided via remote plasma generation or direct plasma generation. In some embodiments, excited hydrogen-containing species can be provided by the thermal disassociation of hydrogen-containing species by exposure to hot surfaces or wires. It will be appreciated that excited hydrogen plasma can include neutral hydrogen-containing species, such as H₂.

The term “oxygen containing species” refers to plasmas made from gases comprising O₂, O₃ and H₂O and combinations thereof.

The term “chemical vapor deposition,” as used herein, refers generally to deposition techniques utilizing vapor phase chemical precursors to deposit a film on a substrate, where the precursors react on the substrate to form a layer. In some embodiments, a precursor can decompose to leave a portion of the precursor such as a metal on the surface. In other embodiments two or more precursors can react at the surface leaving a portion of each precursor as a mixture, alloy, or compound on the surface. Metal organic chemical vapor deposition (MOCVD) is a typical chemical vapor deposition method utilized herein.

The term “adsorption,” as used herein, refers to chemical or physical attachment of atoms or molecules on a surface, such as a substrate surface or a surface of a layer on or over a substrate.

The term “substrate,” as used herein, can refer to any workpiece on which formation of a layer or layers is desired. Substrates can include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof.

The term “surface,” as used herein, refers to a boundary between the environment and a feature of the substrate.

The term “monolayer,” as used herein, refers to a single layer of atoms or molecules. In some embodiments, a monolayer includes a monoatomic monolayer (ML) having a thickness of one atomic layer. In some embodiments, a monolayer includes the maximum coverage of a particular species on a surface. In such a case, all individual members of the surface adsorbed species may be in direct physical contact with the surface of the underlying substrate, or layer. The term “sub-monolayer coverage,” as used herein, refers to a layer of a particular species at a coverage less than one monoatomic monolayer. In some embodiments, a layer of a particular species at sub-monolayer coverage can permit additional adsorption of the species or of another species. In some embodiments, sub-monolayer coverage may be referred to as “pre-wetting” coverage. For example, a layer of a Group III metal, such as gallium (Ga), indium (In) or aluminum (Al), may include Ga, In or Al atoms collectively having a coverage of about 0.5 ML on a surface, which may be provided with respect to the maximum collective coverage of Ga, In or Al atoms on the surface. In some embodiments, the maximum coverage of a species on a surface is determined by the attractive and repulsive interaction between adsorbed species on the surface. In some embodiments, a layer of a species at a coverage of one monolayer cannot permit additional adsorption of the species in the layer. In some embodiments, a layer of a particular species at a coverage of one monolayer may permit the adsorption of another species in the layer.

The term “exposure,” as used herein, refers to the product of pressure (P) and time (t), i.e., P×t, wherein ‘P’ and ‘t’ are provided in units of ton and seconds, respectively. For example, a substrate exposed to a Group III metal precursor at a pressure of 1×10⁻⁶ torr for a period of 60 seconds is contacted with the Group III metal precursor at an exposure (or dosage) of 1×10⁻⁶ torr×60 seconds, or 60×10⁻⁶ torr*s, or 60 Langmuir (L).

The term “precursor,” as used herein, refers to a solid, liquid or vapor phase chemical having a species of interest for deposition on a substrate surface. A Group III metal precursor can include a chemical compound that includes one or more Group III metal atoms, such as one or more of gallium, indium, or aluminum. A Group V precursor can include a chemical that includes one or more Group V atoms, such as one or more of nitrogen, arsenic or phosphorous. A Group II metal precursor can include a chemical compound that includes one or more Group II metal atoms, such as one or more of Zn, Cd, or Hg. A Group VI precursor can include a chemical that includes one or more Group VI atoms, such as one or more of oxygen, sulfur, selenium or tellurium. A Group IV precursor can include a chemical that includes one or more Group IV atoms, such as one or more of silicon, germanium or tin. Upon interaction between a substrate surface and a Group III precursor or a Group V precursor, the Group III precursor or the Group V precursor can dissociate to yield a Group III chemical (or adatoms of the Group III atom) or a Group V chemical (or adatoms of the Group V atom) on the substrate surface. Upon interaction between a substrate surface and a Group II precursor or a Group VI precursor, the Group II precursor or the Group VI precursor can dissociate to yield a Group II chemical (or adatoms of the Group II atom) or a Group VI chemical (or adatoms of the Group VI atom) on the substrate surface. A hydrogen precursor can include H₂ gas. A halide precursor can include Cl₂, Br₂, I₂, HCl, HBr, and/or HI.

The present invention uses two disparate technologies: chemical vapor deposition and plasma exposure, including plasma-assisted, migration enhanced metal-organic chemical vapor deposition—to provide improved processing methods for preparing layers on a substrate. In contrast to previous methods using, for example ALD techniques, there is no need to control the process to deposit a single atomic layer per cycle, and there is no need for a gas purge step between precursor exposures. The present invention further provides for depositing some layers using the combined CVD/plasma methods and some layers using conventional CVD processing, and optionally other processing such as physical vapor deposition, annealing, plasma treatments, etc. The layers can be deposited sequentially, either in separate machines or through the use of a substrate transport system that can move substrates among processing chambers (or modules) without removing the substrates from the sealed machine environment (i.e., through the use of a “cluster tool”).

In accordance with some embodiments of the present invention, the practice of forming layers on a substrate will be described using Group III-V films, Group II-VI films, etc. as exemplary embodiments, although the methods and apparatuses are not limited to these applications.

The improved systems and methods provide the capability to vary the growth conditions and/or the deposition of layers within a single apparatus using both CVD and plasma processes, without removing the substrate from the work environment.

### Systems

Deposition systems and methods for forming layers on a substrate using the systems are disclosed. The deposition systems deposit some layers using combined CVD/plasma methods and some layers using conventional CVD processing, or optionally other processing such as physical vapor deposition, annealing, etc. The layers can be deposited sequentially, either in separate machines or through the use of a substrate transport system that can move substrates among processing chambers (or modules) without removing the substrates from the sealed machine environment (i.e., through the use of a cluster tool).

Embodiments of the deposition system comprise a first substrate transport system capable of loading substrates sequentially into a plurality of processing chambers. A first processing chamber is operable to form a layer by contacting the substrate with one or more precursor gases (i.e., by chemical vapor deposition [CVD]) and to contact the substrate (or a layer deposited on the substrate) with a plasma. The first processing chamber comprises a first processing environment, a second processing environment, a second substrate transport system capable of positioning a substrate for sequential processing in each environment, and a gas control system capable of maintaining isolation of each environment. The first processing environment comprises a system operable to contact the substrate with a plurality of precursor gases, such as metalorganic precursors, for forming layers on the substrate, and the second processing environment comprises a system for contacting the substrate with a plasma. Embodiments of the first processing chamber are described in detail in U.S. Pat. No. 8,143,147 and U.S. patent application Ser. No. 13/546,672, both of which are incorporated by reference herein.

The second substrate transport system can be a planetary wafer transport system comprising a motorized platform rotating about a central axis disposed approximately equidistant from each processing environment, a controller for controlling the time spent in each processing environment and the speed at which the substrate moves between processing environments, and one or more substrate supports capable of independently controlling the temperature of the substrate. The substrate supports can further comprise a motor for providing rotational motion to the substrates. A substrate support can further comprise a heater.

The gas control system of the first processing chamber provides for the introduction and evacuation of gases such that gases from one processing environment are not reactive in another processing environment, thereby providing isolation between the processing environments. The gas control system also comprises a plurality of mass flow controllers for maintaining a predetermined pressure, flow rate and gas composition in the environments.

The first processing chamber can also comprise additional chemical deposition or plasma environments as needed for performing desired processing steps. In some embodiments, the first processing chamber comprises at least two processing environments operable to form a layer by contacting the substrate with a plurality of precursor gases. In some embodiments, the system comprises at least two processing environments operable to contact the substrate with a plasma. The first processing chamber can further comprise a metrology environment for monitoring deposition rate, thickness, composition and the like.

A second processing chamber is operable to deposit one or more layers on the substrate by reaction of precursor gases on the substrate (i.e., by CVD). CVD methods can include metal organic chemical vapor deposition (MOCVD). The second (e.g., CVD) processing chamber comprises a gas emission system capable of providing a plurality of precursor gases for deposition onto a substrate, where the precursors are delivered to the substrate in the same environment and at the same time. The processing chamber is operable to deposit one or more layers on the substrate by reaction of precursor gases on the substrate.

The deposition system can further comprise additional processing chambers, either of the first type or the second, as needed. Similarly, the first processing chamber can comprise two or more environments for contacting the substrate with a plasma. The system can further comprise one or more metrology environments for in situ monitoring of the layer deposition process, as discussed below.

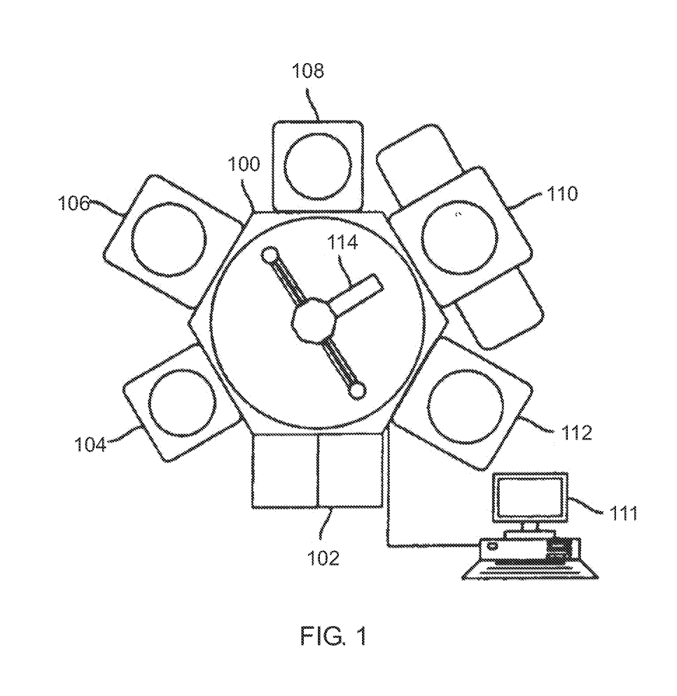

An embodiment of a cluster tool arrangement is shown in FIG. 1. A frame 100 supports a plurality of processing modules or chambers. Frame 100 can be a unitary frame with a controlled environment therein. Load-lock/factory interface 102 provides access into the plurality of modules. Substrate transport system 114 provides for the movement of substrates among the modules as well as in and out of the load-lock/factory interface 102. Processing modules 104-112 can be any set of modules including at least one combined CVD/plasma chamber and at least one conventional CVD chamber. A centralized controller 111 can be used to control all processing modules and the substrate transport system.

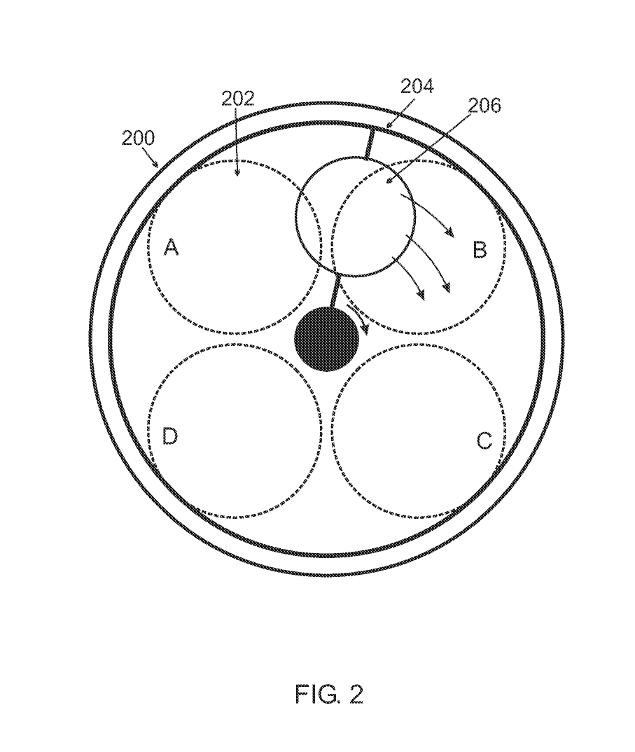

FIG. 2 illustrates an exemplary embodiment of a first processing chamber according to the present invention. An outer chamber 200 having a controlled environmental temperature and pressure is provided containing a plurality of environments 202. Four processing environments are shown in FIG. 2, labeled A-D, although the number may vary according to processing needs and available space. Each environment can be maintained in isolation with the aid of a gas control system that generally maintains each environment at a pressure higher than the outer chamber pressure to prevent cross-contamination between environments. Each environment can be fitted with a particular set of processing or metrology equipment. For example, one or more environments can be operable to perform CVD, one or more environments can be operable to perform plasma contact or deposition, and one or more environments can contain a metrology system according to the need of a particular application. A rotary substrate transport system 204 is provided that can position a substrate 206 in each environment 202 sequentially without removing the substrate 206 from the first processing chamber. Substrates can thereby be processed in sequential environments by any combination of CVD and plasma processing operations plus any intermediate measurements needed to monitor and control the process steps, all without removing the sample to the ambient atmosphere.

The drawings and descriptive examples are intended to be informative and not limiting. For example, there can be more or less than 4 environments and there can be one or more substrates processed within the environment at one time. In addition, there is no required order of treatment in the system. If desired, any environment can be utilized first. For example, a substrate can be subjected to metrology in the metrology environment to measure the surface layers or assess the thickness of a layer already present, before implementing a new layer deposition process. In another example, the substrate can first be contacted with a plasma, and subsequently be processed in the CVD environment.

The system can also be used where one or more environments is effectively turned off for a time. For example, when it is desirable to deposit one or more layers using CVD alone, the plasma generators in the plasma environments can be turned off. If it is desirable to pretreat a substrate with a plasma, for example, to remove surface layers before depositing one or more new layers, the substrate can first be contacted with a plasma, and subsequently with CVD precursors in the CVD environment.

### Chemical Vapor Deposition Environments

The second processing chamber and the second processing environment of the first processing chamber provide a chemical vapor deposition environment (or CVD environment) which utilizes precursor species such as metal organic precursors to deposit a layer on a substrate. Each CVD environment can comprise a showerhead for delivery of precursor gases, capable of delivering specified precursor gases or a mixture of precursor gases as desired. Showerhead technologies are well known in the art; for example, Aixtron MOCVD systems utilize showerhead stations to provide overhead delivery of metal-organic precursors. Each CVD environment is equipped with mass flow controllers for maintaining a predetermined gas flow and gas composition in each environment.

Each environment can further comprise a temperature control system in addition to the temperature control provided by the independent substrate support heater, discussed below.

Typically, the metal-organic precursors include metal with organic ligands, having a high purity of metal (e.g., >99% purity), good stability and volatility. Metal-organic precursors suitable for tantalum deposition include Tris(diethylamido)(ethylimido)tantalum(V), Pentakis(dimethylamino)tantalum(V), and the like; metal-organic precursors suitable for titanium deposition include Titanium(IV) isopropoxide, Tetrakis(dimethylamido)titanium(IV), Bis(tert-butylcyclopentadienyl)titanium(IV), and the like; metal-organic precursors suitable for hafnium deposition include Tetrakis(dimethylamido)hafnium(IV), Dimethylbis(cyclopentadienyl)hafnium(IV), and the like; metal-organic precursors suitable for gallium deposition include Triethylgallium, Trimethylgallium, and the like, metal-organic precursors suitable for indium deposition include Trimethylindium, and the like; metal-organic precursors suitable for aluminum deposition include Trimethylaluminum, and the like; metal-organic precursors suitable for niobium deposition include Bis(cyclopentadienyl)niobium(IV) and the like; metal-organic precursors suitable for silicon deposition include Tris(tert-pentoxy)silanol, Tris(isopropoxy)silanol, and the like; precursors for silicon deposition include silane, disilane, dichlorosilane, silicon tetrachloride and the like; precursors for germanium deposition include germane, digermane, dichlorogermane, germanium tetrachloride and the like; precursors for carbon deposition include methane, ethane, benzene, carbon tetrachloride and the like; metal-organic precursors suitable for zirconium deposition include Tetrakis(ethylmethylamido)zirconium(IV), Bis(cyclopentadienyl)zirconium(IV) dihydride, and the like; metal-organic precursors suitable for yttrium deposition include Tris[N,N-bis(trimethylsilyl)amide]yttrium, and the like; metal-organic precursors suitable for cadmium deposition include Cadmium acetylacetonate, and the like; metal-organic precursors suitable for zinc deposition include Diethylzinc, and the like; metal-organic precursors suitable for tungsten deposition include Bis(tert-butylimino)bis(dimethylamino)tungsten(VI), and the like; metal-organic precursors suitable for selenium deposition include diethyl selenide, and the like. Additional components of layers can be deposited using MOCVD environment. For example, Group V members such as P, As, M, Sb and Bi can be added to a layer through the MOCVD process. Group V precursors suitable for MOCVD deposition include phosphine, ammonia, hydrazine, Triphenylarsine, Triphenylantimony(III) and Tris(dimethylamido)antimony(III), Triphenylbismuth 98%, and so forth.

### Plasma Environments

The second processing environment of the first processing chamber comprises an isolated region of the deposition system for contacting a substrate with a plasma. In some embodiments, the active species generated in the plasma can be provided to the substrate via gas flow directing the plasma at the substrate surface. In some embodiments, the active species generated in the plasma can be provided to the substrate via diffusion of the active species from the plasma generation region to the substrate surface.

In some embodiments, each plasma environment is equipped with mass flow controllers for maintaining a predetermined pressure and gas composition in each environment. The pressure is preferably set at an elevated level relative to the chamber pressure so that there is a net flux of gases from the plasma environment to the first processing chamber, which can then be evacuated using the chamber gas control system, thereby avoiding contamination of other environments present in the system.

The energy to generate the plasma may be supplied via a variety of methods, such as, e.g., ultraviolet radiation, infrared radiation, microwave radiation, inductive coupling and capacitive coupling, such as with the aid of a plasma generator. The plasma generator can be a direct plasma generator (i.e., direct plasma generation) or a remote plasma generator (i.e., remote plasma generation). In the absence of coupling energy, plasma generation is terminated. For remote plasma generation, plasma-excited species of a particular vapor phase chemical (e.g., nitrogen-containing plasma species) may be formed in a plasma generator in fluid communication with an environment having a substrate to be processed. For example, the ions can be directed to the substrate using a gas flow or electrical fields.

In some embodiments, energy may be applied to the precursors by exposure of a precursor to hot (or heated) surfaces or wires, where the interaction of the gas with the heated surfaces or wires generates excited (or activated) species of the gas. It is known in the art that atomic hydrogen (H) can be produced by exposure of hydrogen gas (H₂) to hot wires or surfaces, where the surfaces are at a temperature typically in excess of 1000° C.

The properties of the excited species in the plasma can be tailored by appropriate choice of constituent gases, electron temperature, ion energy and ion density. A specified ion density and mean ion energy at the substrate surface can be targeted. Similarly, negligible ion density at the substrate can be targeted, and instead a desired density of specified excited species of neutral atoms and molecules can be provided.

In some embodiments, plasma is generated in a Group V precursor which includes a nitrogen-containing species. In some embodiments, the Group V precursor includes plasma-excited species of nitrogen. In some embodiments, the Group V precursor comprises active neutral species of nitrogen. In some embodiments, the Group V precursor comprises nitrogen species having the lowest excited state of molecular nitrogen (A³Σᵤ⁺).

In some embodiments, plasma-excited species of nitrogen may include a nitrogen and hydrogen-containing species formed by providing energy to a mixture of N₂ and H₂ gases, NH₃, a mixture of N₂ and NH₃, hydrazine (N₂H₄), and/or a mixture of N₂ and N₂H₄. In some embodiments, plasma-excited species of nitrogen include NHₓ, wherein ‘x’ is a number greater than or equal to 1. For example, plasma-excited species of nitrogen may include one or more of NH, NH₂ and NH₃, and ions and radicals of such species, such as, for example, NH⁺, NH₂⁺, NH₃⁺. In some embodiments, plasma-excited species of nitrogen are formed by inductively coupling energy to a mixture of N₂ and H₂ gases having a ratio of N₂ and H₂ flow rates of about 0.5:1, or 1:1, or 2:1, or 3:1, or 4:1, or 5:1.

The plasma environment can provide a substrate with exposure to reactive species generated by the plasma; the reactive species generally are reactive with constituents in a layer on a substrate under the appropriate environmental conditions of temperature, pressure and composition. In some embodiments, reactive species generated by plasmas can include those resulting from Group II precursors, or Group III precursors, or Group V precursors, or Group VI precursors, or hydrogen, or combinations of these precursors. In some embodiments, reactive species generated by plasmas can include those resulting from inert gases (e.g., plasmas made from noble gases), and can be used to effect surface modifications (e.g. roughening or texturing). In some embodiments, reactive species generated by plasmas can include those resulting from mixtures of inert gases with any of Group II precursors, or Group III precursors, or Group IV precursors or Group V precursors, or Group VI precursors, or hydrogen, or combinations of these precursors.

Use of a halogen plasma, such as a fluorine plasma, can require low ion energy to prevent ion bombardment damage and associated etching. The low ion energy plasma can be formed using an inductive pulsed plasma, a continuous wave capacitive source plasma, and a continuous wave mixed inductive and capacitive source plasma.

Fluorination of a layer can be effected using a fluorine plasma which provides atomic-F formed by co-flowing F₂ and an inert gas plasma such as argon, or helium, or neon, or krypton, or xenon. Besides F₂, other fluorine-containing gases may be used to form the fluorine plasma, such as NF₃, HF, or combinations thereof. In addition, mixtures with other gases such as nitrogen and oxygen can be used in place of or in combination with inert gases. Preferably, the gases used in this process are carbon free.

The plasma environment can provide a substrate with exposure to excited nitrogen-containing species (a nitrogen plasma). A nitrogen plasma can be utilized, for example, to introduce nitrogen into a film (i.e., to perform nitridation) or to supply the nitrogen for depositing Group III-nitrogen films. The excitations of nitrogen in the plasma can comprise ions, excited neutrals, or combinations thereof.

The plasma environment can provide a substrate with exposure to excited oxygen-containing species (an oxygen plasma). An oxygen plasma can be utilized, for example, to introduce oxygen into a film (i.e., to perform oxidation), to reduce carbon contamination, or to supply the oxygen for depositing metal oxide films, or to supply the oxygen for Group II-oxygen or Group III-oxygen films.

The plasma environment can provide a substrate with exposure to excited hydrogen-containing species (a hydrogen plasma). A hydrogen plasma can be utilized, for example, to assist in managing metal droplet formation, to reduce carbon contamination, or to provide reactive hydrogen for electronic defect passivation within semiconductor layers.

The plasma environment can provide a substrate with exposure to excited inert gas-containing species (an inert plasma). An inert gas plasma can be utilized, for example, to provide non-thermal energy to the growth front of the deposited film. Typical inert gas plasmas comprise noble gases such as Ar, He, Ne, Kr, or Xe.

### Substrate Transport System

The deposition system comprises a first substrate transport system capable of loading substrates sequentially into a plurality of processing chambers. The first substrate transport system allows a substrate to be processed in multiple processing chambers without removing the substrate from a sealed environment. The arrangement of processing chambers and transport system can be referred to as a “cluster tool.”

A second substrate transport system is operable with the first processing chamber for moving the substrate among one or more local CVD environments and one or more plasma environments. In some embodiments, the second substrate transport system is a planetary wafer transport system comprising a motorized platform rotating about a central axis disposed approximately equidistant from each processing environment. The transport system utilizes a controller for controlling the time spent in each processing environment and the speed at which the substrate moves between processing environments. In some embodiments, the system moves the substrate through a global rotation that passes sequentially through each of the environments present in the chamber. In some embodiments, the substrate support further comprises a motor for providing rotational motion to the substrate. In some embodiments, the substrate support comprises a linear transport system capable of moving the substrates between processing environments.

The transport system further comprises one or more substrate supports. Preferably, the substrate supports are capable of independently controlling the temperature of the substrate; for example, the substrate support can further comprise a heater to provide independent temperature control for the substrate. The temperature control can be provided by any convenient method, for example, by RF heating (induction) or resistive heating. Typical operating substrate temperatures range from 100° C. to 1300° C.

With reference to FIG. 2, the substrate transport system 204 is capable of positioning a substrate for sequential processing in each environment. Depending on the desired processing, in some embodiments the substrate can move at constant speed through sequential processing and metrology environments, for example, by rotating the entire transport system at a constant angular velocity of 1-1000 rpm, typically about 200 rpm. In some embodiments, the transport system is used as a positioning system to move substrates from one environment to another, stopping at each for a processing time, and angular velocity is zero.

In some embodiments, only one substrate support is provided as shown in the FIG. 2; in some embodiments a plurality of substrate supports can be provided to enable parallel processing of different substrates in different environments. An additional, independent rotational motion can be provided about a set of second axes defined by the center of one or more of a group of substrates, where one such second axis exists for each group, in order to provide more uniform deposition or treatment within any one processing environment. The substrate supports can be rotated at a constant or variable angular velocity of 1-1000 rpm.

### Gas Control System

The gas control system for the first processing chamber is capable of maintaining isolation of each environment therein. The gas control system provides for the introduction and evacuation of gases such that gases from one environment do not react in another environment, thereby providing isolation between the processing environments. The gas control system provides pressures in each processing environment that are elevated relative to the chamber pressure. Each processing chamber can comprise its own gas control system.

The gas control system comprises a plurality of pumps for maintaining a predetermined pressure in each processing environment. The gas control system also comprises a plurality of mass flow controllers for maintaining a predetermined pressure and gas composition in each environment. Each CVD environment, each plasma environment and each metrology environment can be provided with a positive gas flow (i.e., positive pressure) that is effective to keep gases originating from one environment from entering the remaining environments; i.e., pressures in each environment are elevated relative to the chamber pressure.

A plurality of gas evacuation outlets are provided for removal of gases within the chamber. The gas control system further comprises a plurality of gas pumps for maintaining a predetermined pressure in the chamber. The gas control system also comprises a plurality of mass flow controllers for maintaining a predetermined pressure and gas composition in each environment. Typical pressures range from 1 mT to 760 T.

### Metrology Environments

In situ thin film measurements can be done in a separate environment in the first processing chamber which is maintained for optimal stability and repeatability of the measurements. In situ monitoring allows the determination of layer thickness, surface quality, deposition rate, uniformity across the substrate, uniformity in one substrate relative to another, composition of layers, temperature of the substrate and layers, and curvature induced in the substrate during growth. In situ monitoring also allows accurate statistical process controls on layer deposition. If desired, the data from these measurements may be used for real-time closed loop control of the metal-organic deposition and plasma environments.

Accordingly, the system further comprises at least one metrology environment for practicing metrology techniques on substrates as the film is being formed so that the process can be monitored in situ while the process is ongoing, without removing the wafer from the system or destroying it. Preferably, the metrology environment comprises one or more stations that utilize nondestructive methods, such as acoustic, magnetic or optical methods. Exemplary metrology stations include the apparatus and capability for performing pyrometry (measuring temperature), reflectometry, Reflectance Anisotropy Spectroscopy, ellipsometry, Fourier Transform infrared (FTIR) spectroscopy, or the like. Metrology environments can also be provided as components of the system, or in the CVD processing environments.

The metrology environment preferably is also served by the gas control system, and is provided with a flow of nitrogen or other gas which is nonreactive with the metrology environment systems. Preferably the gas flow is effective to prevent deposition of CVD or plasma constituents onto the surfaces in the metrology environment, and is effective to keep the optics clear and the instruments free of corrosive materials and damage.

### Methods of Forming Layers

Methods of depositing at least one layer by a first method in a first processing chamber, and depositing at least one layer by a second method in a second processing chamber are disclosed. The first method comprises forming a first layer on a substrate in a first processing chamber. The first processing chamber comprises a first processing environment operable to form a layer by contacting the substrate with one or more precursor gases and a second processing environment operable to contact the substrate with a plasma, i.e., the first processing environment is operable to perform chemical vapor deposition, and the second processing environment is operable to contact the substrate with plasma. Precursors typically include Group II, Group III and/or Group IV precursors. The forming and contacting steps can be performed in a chamber comprising a first processing environment for performing chemical vapor deposition on the substrate, and a second processing environment for contacting the substrate with a plasma; a substrate transport system capable of positioning a substrate for sequential processing in each environment, and a gas control system capable of maintaining isolation of each environment. The forming and contacting steps can be repeated until layers of desired composition and thickness are formed. The forming and contacting steps can be performed in additional distinct environments to form devices having multiple distinct layers, such as Group III-V, Group II-VI or Group IV thin film devices.

The second method comprises forming a layer from a precursor on a substrate in a chemical vapor deposition environment. In some embodiments, the CVD deposition environment is not provided with a separate processing environment for contacting the substrate with a plasma. In some embodiments, the CVD processing chamber can further comprise a plasma generator to enable the formation of layers using plasma-assisted CVD (PECVD).

In some embodiments, a plurality of layers are deposited onto a silicon substrate, wherein at least one layer is an AlN layer which is deposited by the first method, and at least one layer is an AlGaN layer which is deposited by the second method. This approach is illustrated in Example 1.

In some embodiments, a plurality of layers are deposited onto a silicon substrate, wherein at least one layer is an AlN layer which is deposited by the first method, at least one layer is an AlGaN layer which is deposited by the first method, and at least one layer is deposited by the second method (e.g., an n-type doped GaN layer). This approach is illustrated in Example 2.

In some embodiments, a plurality of layers are deposited onto a silicon substrate, wherein at least one layer is an AlN layer which is deposited by the first method, and at least one layer is an undoped GaN layer which is deposited by the second method.

In some embodiments, a plurality of layers are deposited onto a silicon substrate, wherein at least one layer is an AlN layer which is deposited by the first method, and at least one layer is an n-type doped GaN layer which is deposited by the second method.

In some embodiments, wherein a plurality of layers are deposited onto a silicon substrate, wherein at least one layer is an AlN layer which is deposited by the first method, and at least one layer is an InGaN layer which is deposited by the second method.

In some embodiments, a plurality of layers are deposited onto a silicon substrate, wherein at least one layer is an AlN layer which is deposited by the first method, at least one layer is an undoped GaN layer which is deposited by the second method, and at least one layer is an InGaN layer which is deposited by the first method.

In some embodiments, a plurality of layers are deposited onto a silicon substrate, wherein at least one layer is an AlN layer which is deposited by the first method, at least one layer is an undoped GaN layer which is deposited by the first method, and at least one layer is an InGaN layer which is deposited by the second method.

There is no presumed order to the formation of the first layer or the second layer in the first processing chamber nor is there any presumed order in the use of any chambers or the number of layers produced sequentially in one chamber. For example, the layer formed using chemical vapor deposition can be formed adjacent to the substrate, or the layer formed using plasma can be formed adjacent to the substrate. In addition, the substrate can be treated with a plasma either before or after layers are formed thereon using chemical vapor deposition or plasma deposition. In some embodiments, contacting the substrate with plasma in a plasma processing environment can be effective to deposit atoms from the plasma onto the substrate. In some embodiments, contacting the substrate with plasma in the second processing environment is effective to treat the surface of the substrate or of a layer disposed on the substrate. Treatment with a plasma can be effective to enhance metal atom migration on the layer, lower the temperature required for growth of the layer, reduce contaminants in the layer, or combinations thereof. Advantageous treatments include: pre-deposition cleaning of surface contaminants on the substrate, for example hydrocarbon molecules, water molecules, hydroxyl molecules, metal atoms and/or molecules comprising metal contamination can be treated by exposure to a hydrogen containing plasma, a nitrogen containing plasma, and/or an inert gas plasma where the substrate is maintained at either room temperature or above room temperature. Other treatments include the use of a hydrogen containing plasma for the removal of adsorbed carbon atoms or hydrocarbon groups which are present from the decomposition of metal-organic precursors; roughening and/or texturing of the surface by exposure to a hydrogen containing plasma, a nitrogen containing plasma, and/or an inert gas plasma. Other advantageous applications may be known to those skilled in the art.

Further, additional layers can be formed using either the first processing environment or the second processing environment (i.e., the plasma environment). The methods can be performed to form devices having multiple distinct layers, such as Group III-V or Group II-VI thin film devices. In some embodiments, the low-temperature deposition chamber can be used to form one or two “seed” layers or “barrier” layers, and then the CVD chamber can be used to deposit a plurality of device layers.

In some embodiments, the plasma is a reactive plasma comprising one or more of a halogen, oxygen, water, nitrogen, hydrogen, ammonia, hydrazine, methane, ethane, hydrogen chloride. In some embodiments, the plasma is an inert plasma comprising one or more of argon, krypton, helium, neon, or xenon. In some embodiments, the plasma is a neutral plasma.

In some embodiments, the method is practiced utilizing a system comprising at least two processing environments for performing chemical vapor deposition on the substrate, where the processing environments can be the same or different. In some embodiments, the method is practiced utilizing a system comprising at least two processing environments for contacting the substrate with a plasma, where the processing environments can be the same or different.

In some embodiments, the methods can be performed to prepare a Group III-V, Group II-VI, or Group IV thin film device. In some embodiments, the methods can be performed to prepare a light emitting diode (LED) having a Group III-V thin film. The LED can comprise a substrate such as silicon, and additional layers such as an AlN layer, a GaN layer, or an AlGaN layer.

Advantageously, the amount of material that can be deposited in each cycle can be selected by the CVD rate and the speed with which the substrate is contacted with the different environments (i.e., the rotation speed). The thickness of the deposited film that is exposed to the plasma is tunable and can be less than one monolayer per cycle or more than one monolayer per cycle. Embodiments of the present invention improve over the self-limited nature of atomic layer deposition (ALD) processes, because the exposure to precursors and additional constituents of layers can be provided by both CVD and plasma, do not require separation into exposure and purge phases, and do not limit the layer thickness deposited.

In some embodiments, the substrate is contacted for a time period no more than that required to form a Group III-V thin film at sub-monolayer coverage per cycle of deposition. In some embodiments, contacting the substrate with the Group V precursor forms a Group III-V thin film having a thickness per cycle of deposition less than about 1 monolayer (ML), or less than 0.95 ML, or less than 0.9 ML, or less than 0.85 ML, or less than 0.8 ML, or less than 0.75 ML, or less than 0.7 ML, or less than 0.65 ML, or less than 0.6 ML, or less than 0.55 ML, or less than 0.5 ML, or less than 0.45 ML, or less than 0.40 ML, or less than 0.35 ML, or less than 0.30 ML, or less than 0.25 ML, or less than 0.20 ML, or less than 0.15 ML, or less than 0.10 ML, or less than 0.05 ML. In some embodiments, contacting the substrate in the second reaction space with the Group V precursor forms a Group III-V thin film having a thickness per cycle of deposition up to about 0.05 ML, or 0.1 ML, or 0.15 ML, or 0.2 ML, or 0.25 ML, or 0.3 ML, or 0.35 ML, or 0.4 ML, or 0.45 ML, or 0.5 ML, or 0.55 ML, or 0.6 ML, or 0.65 ML, or 0.7 ML, or 0.75 ML, or 0.8 ML, or 0.85 ML, or 0.9 ML, or 0.95 ML, or 1 ML. In some embodiments, contacting the substrate in the second reaction space with the Group V precursor forms a Group III-V thin film at sub-monolayer coverage per cycle of deposition.

In some embodiments, for example, one MOCVD environment provides a mixture of trimethylgallium and ammonia to deposit a layer of GaN, while a second MOCVD environment provides a mixture of trimethylindium and trimethylgallium along with ammonia to form a second layer have a different composition. Alternatively, the nitrogen component can be introduced using a nitrogen-containing plasma in an environment for contacting a substrate with plasma. In some embodiments, the MOCVD process using ammonia and the plasma process can be combined so that nitridation is effected without requiring prolonged exposure, high temperatures, or high flow rates of ammonia. For example, trimethylgallium and ammonia can be provided in one MOCVD environment and a nitrogen-containing plasma can be provided in a plasma environment such that GaN is deposited on the substrate using a smaller amount of ammonia or at a lower temperature than would be required using a conventional MOCVD process.

The forming and contacting steps can be performed in any order as desired to effect a particular result. For example, if it is desired to treat the substrate with a plasma prior to depositing any layers, the substrate can be contacted with plasma in a plasma environment prior to performing CVD to deposit a layer. Similarly, if it is desired to treat the substrate with a plasma after a layer has been deposited by CVD, the plasma environment can be utilized after the CVD environment. Layers can be formed in a CVD processing chamber either before or after layers are formed in a low temperature deposition processing chamber.

In some embodiments, contacting the substrate with plasma in a plasma environment is effective to deposit atoms from the plasma onto the substrate. In some embodiments, contacting the substrate with plasma in a plasma environment is effective to treat the layers to modify some aspect of the layer composition, morphology or properties. For example, plasma treatment can enhance metal migration on the layer, lower the temperature required for growth of the layer, reduce contaminants in the layer, or combinations thereof.

The plasma can be formed from excitations of one or more of a halogen, oxygen, water, nitrogen, hydrogen, ammonia, hydrazine, methane, ethane, or hydrogen chloride gases, and combinations thereof. Preferred halogens include fluorine or chlorine. Additionally, the plasma can comprise the inert gases argon, krypton, helium, neon, or xenon, or mixtures thereof. In some embodiments, the method comprises utilizing a second environment for performing CVD on the substrate.

In some embodiments, the method comprises utilizing a second environment for performing CVD on the substrate. In some embodiments, the method comprises utilizing a second environment for contacting the substrate with a plasma.

To form metal or semiconductor containing layers, the metal-organic precursor can comprise, for example, a Group III precursor, a Group II precursor or a Group IV precursor, or mixtures thereof. In some embodiments, the metal-organic precursor comprises a transition metal, lanthanide, actinide, or the like. Typically, the plasma can comprise a Group V precursor, or a Group VI precursor. Alternatively, the Group V precursor or Group VI precursor can be provided in the MOCVD deposition along with the metal-organic precursor.

In some embodiments, the metal-organic precursor is a Group III precursor and the plasma comprises a Group V precursor. In some embodiments, the Group III precursor and the Group V precursor are provided in the environment for performing MOCVD on the substrate. In some embodiments, the Group III precursor and the Group V precursor are provided in the environment for performing MOCVD on the substrate, and the plasma further comprises a Group V precursor.

The Group III precursor preferably comprises boron, aluminum, gallium or indium. The Group V precursor preferably comprises nitrogen, ammonia, hydrazine, phosphine, or arsine. In some embodiments, the plasma comprises a nitrogen containing species.

In some embodiments, the layer formed is a Group III-V thin film comprising InₓGa₁₋ₓN, wherein x is a number greater than 0 and less than 1, or x is at most about 0.99. In some embodiments, a Group III-V thin film device can be formed. Representative thin film devices include light emitting diodes (LED) having a Group III-V thin film, photovoltaic solar cells having a Group III-V thin film, quantum well heterostructure devices having a Group III-V thin film, multiple quantum well heterostructure devices having a Group III-V thin film, and so forth. In some embodiments, the layer formed is a gallium nitride thin film, an indium gallium nitride thin film, an aluminum nitride thin film, indium nitride thin film, aluminum gallium nitride thin film, or indium gallium aluminum nitride thin film, or the like. The layer formed can comprises epitaxial layers of gallium nitride and indium gallium nitride, aluminum nitride, aluminum gallium nitride, gallium nitride, indium gallium nitride, or aluminum indium gallium nitride.

In some embodiments, the metal-organic precursor is a Group II precursor and the plasma comprises a Group VI precursor. For example, the metal-organic precursor can be a zinc precursor and the plasma is formed from oxygen, to form a layer comprising ZnO.

In some embodiments, the precursor is a Group IV precursor such as CCl₄, CH₄, SiCl₄, SiH₄, GeCl₄, or GeH₄. In some embodiments, a layer is formed using a Group IV precursor in an CVD environment, and the plasma is formed from a halogen, oxygen, nitrogen, or hydrogen to form a layer comprising a Group IV halide material, a layer comprising a Group IV oxide material, a layer comprising a Group IV nitride material, or a layer comprising a Group IV hydride material, or the like. Additional plasma treatments can be included to form layers having multiple constituents derived from the plasmas. Thus, when a layer is formed by contacting the substrate with a first plasma environment comprising a plasma formed from oxygen to form an oxide layer, the method can further include contacting the substrate with a second plasma environment comprising a plasma formed from nitrogen to form an oxynitride layer. In some embodiments, the layer formed comprises silicon, carbon, oxygen, nitrogen, or mixtures thereof.

In some embodiments, the metal-organic precursor is a transition metal precursor, or mixtures thereof. Examples of transition metals that can be used in MOCVD include tantalum, hafnium, titanium, zirconium, and the like. Metal-organic precursors suitable for tantalum deposition include Tris(diethylamido)(ethylimido)tantalum(V), Pentakis(dimethylamino)tantalum(V), and the like; metal-organic precursors suitable for titanium deposition include Titanium(IV) isopropoxide, Tetrakis(dimethylamido)titanium(IV), Bis(tert-butylcyclopentadienyl)titanium(IV), and the like; metal-organic precursors suitable for hafnium deposition include Tetrakis(dimethylamido)hafnium(IV), Dimethylbis(cyclopentadienyl)hafnium(IV), and the like; metal-organic precursors suitable for zirconium deposition include Tetrakis(ethylmethylamido)zirconium(IV), Bis(cyclopentadienyl)zirconium(IV) dihydride, and the like.

In some methods, a layer is formed by depositing a layer of transition metal or transition metal precursor on a substrate, and contacting the substrate with a plasma formed from a Group V precursor, or a Group VI precursor. In some embodiments, the plasma is formed from a halogen, oxygen, nitrogen, or hydrogen. In some embodiments, the metal-organic precursor is a transition metal precursor and the plasma is formed from oxygen to form an oxide layer on the substrate. In some embodiments, the metal-organic precursor is a transition metal precursor and the plasma is formed from nitrogen to form a nitride layer. In some embodiments, the metal-organic precursor is a transition metal precursor and the plasma is formed from oxygen to form an oxide layer, and the substrate is further contacted with a plasma formed from nitrogen to form an oxynitride layer. In some embodiments, the layer formed comprises a transition metal oxide, a transition metal nitride or a transition metal oxynitride.

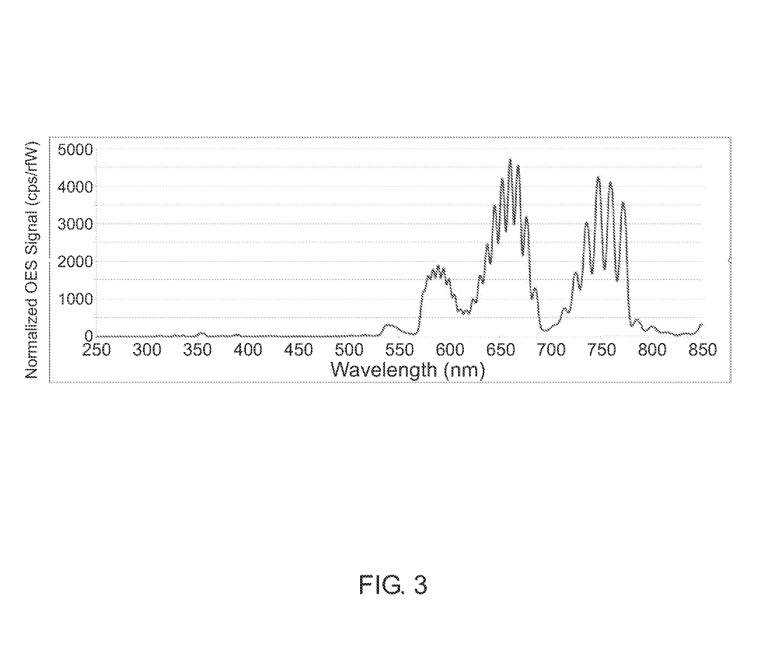

In some embodiments, the nitrogen plasma generated is predominately active neutral species of nitrogen having the lowest excited state of molecular nitrogen (A³Σᵤ⁺). FIG. 3 shows a schematic of an optical emission spectrum of a radio-frequency inductively coupled plasma excitation of N₂ gas, where the majority of optical transitions are into the lowest energy band for excited N₂ molecules (approximately 600 to 800 nm emission bands, referred to as the first positive series), showing transitions which terminate in a band of states with a minimum excitation energy of approximately 6 electron volts (eV). The absence of strong emission in the approximate range 300 to 400 nm, referred to as the second positive series, may be indicative of a lack of higher energy excited N₂ molecules. These active neutral species formed from the excitation of N₂ gas can be used for deposition of III-V layers such as InGaAlN thin films.

Referring to FIG. 2, one implementation of the invention is as follows: Environment A: MOCVD reaction environment; Environment B: reactive plasma environment, e.g., N₂ plasma; Environment C: inert plasma environment, e.g., Ar plasma or H₂/Kr plasma; and Environment D: metrology environment. This implementation of the invention can be used in the following exemplary manner: a silicon substrate is contacted with trimethyl aluminum in a first MOCVD environment at a pressure of about 0.5 T and at 700° C. The first exposure of trimethylaluminum is sufficient to form an aluminum thin film at a coverage of about 0.5 ML. Next, the substrate, heated to a temperature of about 700° C., is rotated to a plasma environment and contacted with a mixture of N₂ and H₂, at a pressure of about 0.5 T. Plasma power of about 500 W is provided to the mixture to generate excited species of N₂ and H₂. Plasma power is sufficient to generate active neutral species of nitrogen having the lowest excited state of molecular nitrogen (A³Σᵤ⁺). The exposure to excited species of N₂ and H₂ is sufficient to produce a layer of aluminum nitride on the surface of the substrate. Next, the substrate, heated to a temperature of about 900° C., is rotated to a second plasma environment and contacted with excited hydrogen-containing species, including hydrogen radicals and ions, at a pressure of about 0.5 T. Excited hydrogen-containing species are formed by providing plasma power of about 500 W to H₂. The excited species of hydrogen, among other things, provide reactive hydrogen to scavenge residual carbon from the metal organic precursors and reduce the in-film carbon contamination. Next, the substrate, is rotated to a metrology environment and the thickness of the resulting film is measured. Next, the substrate is rotated to the first MOCVD environment, and the steps above are repeated to provide a Group III-V thin film of AlN having, in total, a thickness of about 100 nanometers (“nm”). The substrate can then be processed in a CVD chamber on the cluster tool to deposit a layer of GaN, for example. Alternatively, the GaN layer can be deposited prior to the deposition of the AlN layer.

Another implementation may be as follows: Environment A: CVD reaction environment; Environment B: reactive plasma environment (O₂ plasma); Environment C: H₂ plasma environment (H₂ plasma); and Environment D: metrology environment.

This implementation of the invention can be used in the following exemplary manner: a silicon substrate is contacted with zinc precursor (e.g., diethylzinc) in a first CVD environment at a pressure of about 0.5 T and at 700° C. The first exposure of zinc is sufficient to form a zinc thin film at a coverage of about 0.5 ML. Next, the substrate, heated to a temperature of about 600° C., is rotated to a plasma environment and contacted with O₂, at a pressure of about 0.5 T. Plasma power of about 500 W is provided to the mixture to generate excited species of O₂. The exposure to excited species of O₂ is sufficient to produce a layer of zinc oxide on the surface of the substrate. Next, the substrate, heated to a temperature of about 900° C., is rotated to a second plasma environment and contacted with excited hydrogen-containing species, including hydrogen radicals and ions, at a pressure of about 0.5 T. Excited hydrogen-containing species are formed by providing plasma power of about 500 W to H₂. The excited species of hydrogen, among other things, provide reactive hydrogen to scavenge residual carbon from the metal organic precursors and reduce the in-film carbon contamination. Next, the substrate is rotated to a metrology environment and the thickness of the resulting film is measured. Next, the substrate is rotated to the first MOCVD environment, and the steps above are repeated to provide a Group II-VI thin film of ZnO having, in total, a thickness of about 500 nm. The substrate can then be processed in a CVD chamber on the cluster tool to deposit a layer of GaN, for example. Alternatively, the GaN layer can be deposited prior to the deposition of the ZnO layer.

Another implementation may be as follows: Environment A: MOCVD reaction environment; Environment B: reactive plasma environment (e.g., O₂ plasma); Environment C: metrology. This implementation of the invention can be used in the following exemplary manner: a silicon substrate is contacted with strontium and titanium precursors (e.g., Bis(2,2,6,6-tetramethyl-3,5-heptanedionato)strontium hydrate and Cyclopentadienyl(cycloheptatrienyl) titanium(II)) in a first MOCVD environment at a pressure of about 0.5 T and at 650° C. The first exposure of strontium and titanium precursors is sufficient to form a strontium and titanium thin film at a coverage of about 0.5 ML. Next, the substrate, heated to a temperature of about 650° C., is rotated to a plasma environment and contacted with O₂, at a pressure of about 0.2 T. Plasma power of about 500 W is provided to the mixture to generate excited species of O₂. The exposure to excited species of O₂ is sufficient to produce a layer of SrTiO₃ on the surface of the substrate. Next, the substrate is rotated to a metrology environment and the thickness of the resulting film is measured. Next, the substrate is rotated to the first MOCVD environment, and the steps above are repeated to provide a Group III-V thin film of SrTiO₃ having, in total, a thickness of about 50 nm. The substrate can then be processed in a CVD chamber on the cluster tool to deposit a layer of GaN, for example. Alternatively, the GaN layer can be deposited prior to the deposition of the SrTiO₃ layer.

Another implementation of the invention is as follows: Environment A: CVD reaction environment; Environment B: reactive plasma environment, e.g., H₂Se plasma; Environment C: metrology environment.

This implementation of the invention can be used in the following exemplary manner: a silicon substrate is contacted with a mixture of the precursors trimethylgallium, trimethylindium and copper precursor (e.g., bis(t-butylacetoacetato)copper(II)) in a first MOCVD environment at a pressure of about 0.5 T and at 600° C. The first exposure of trimethylgallium, trimethylindium and copper precursor is sufficient to form a Cu—In—Ga thin film at a coverage of about 0.5 ML. Next, the substrate, heated to a temperature of about 600° C., is rotated to a plasma environment and contacted with H₂Se at a pressure of about 0.2 T. Plasma power of about 500 W is provided to the mixture to generate excited species of H₂Se, HSe, H₂ and Se. Next, the substrate is rotated to a metrology environment and the thickness of the resulting film is measured. Next, the substrate is rotated to the first MOCVD environment, and the steps above are repeated to provide a thin film of Cu—In—Ga—Se having, in total, a thickness of about 2 microns. The substrate can then be processed in a CVD chamber on the cluster tool to deposit a layer of GaN, for example. Alternatively, the GaN layer can be deposited prior to the deposition of the Cu—In—Ga—Se layer.

Another implementation of the invention is as follows: Environment A: CVD reaction environment; Environment B: reactive plasma environment, e.g., N₂ plasma; Environment C: inert plasma environment, e.g., Ar plasma or H₂/Kr plasma; and Environment D: metrology environment.

This implementation of the invention can be used in the following exemplary manner: a silicon substrate is contacted with trimethylgallium and NH₃ in a first MOCVD environment at a pressure of about 0.5 T and at 900° C. The first exposure of trimethylgallium is sufficient to form a gallium nitride thin film at a coverage of about 0.5 ML. Next, the substrate, heated to a temperature of about 900° C., is rotated to a plasma environment and contacted with N₂ at a pressure of about 0.2 T. Plasma power of about 500 W is provided to the mixture to generate excited species of N₂. Plasma power is sufficient to generate active neutral species of nitrogen having the lowest excited state of molecular nitrogen (A³Σᵤ⁺). The exposure to excited species of N₂ is sufficient to produce a layer of gallium nitride on the surface of the substrate and provide additional chemical reactivity and non-thermal energy to the growth front. Next, the substrate, heated to a temperature of about 900° C., is rotated to a second plasma environment and contacted with excited hydrogen-containing species, including hydrogen radicals and ions, at a pressure of about 0.5 T. Excited hydrogen-containing species are formed by providing plasma power of about 500 W to H₂. The excited species of hydrogen scavenge residual carbon from the metal organic precursors and reduces the in-film carbon contamination. Next, the substrate is rotated to a metrology environment and the thickness of the resulting film is measured. Next, the substrate is rotated to the first CVD environment, and the steps above are repeated to provide a Group III-V thin film of GaN having, in total, a thickness of about 4 microns. The substrate can then be processed in a CVD chamber on the cluster tool to deposit a layer of InGaN, for example. Alternatively, the InGaN layer can be deposited prior to the deposition of the GaN layer. The exemplary processes can be performed sequentially to build layers of varying thickness and composition. For example the AlN (the first implementation above) formed on a Si (111) wafer, followed by the GaN process (the fourth process). This approach allows the multilayer film to be grown with the best deposition method for a given material. In the case of AlN, the preferred deposition method is cyclic deposition of Al metal layers followed by conversion to AlN by exposure to the nitrogen plasma; in the case of GaN the preferred method is the cyclic treatment of the CVD GaN film with the nitrogen plasma.

Unlike ALD processes, the inventive methods and apparatuses are not restricted to single layer deposition, and layers of any desired thickness can be deposited using any chosen deposition method. Unlike PECVD, the inventive methods and apparatuses can be practiced where only the desired precursors, and not all precursors, are subject to plasma excitation, due to the ability to provide spatial separation of the CVD environment and the plasma excitation environments. This separation is useful in preventing unwanted gas phase reactions and contamination of environments is minimized using gas control systems that prevent the dust formation prevalent in certain PECVD methods and systems. Deposition of layers is expedited because substrates do not have to be removed to separate processing environments.

### Applications

The inventive systems and methods are applicable to a wide range of technologies, in particular, the deposition of the Group III-V materials, such as the GaN materials system (AlN, InN, GaN and their alloys). Accordingly, the systems and methods can be applied to preparation of Group III-V, Group II-VI, or Group IV thin film devices, including the research and development of optoelectronics devices such as light emitting diodes (LEDs), infrared LEDs, lasers, and solar cells, generally known as III-V technology. In some embodiments, the system can be used to prepare blue or green LEDs using InGaN/GaN multilayer device structures. For example, the system described herein can readily provide improved methods of preparing the multi-quantum well layers and thicknesses, reducing contamination of instruments with dust and other unwanted reaction products, thereby facilitating research and development efforts in this technologically challenging area.

Exemplary Group III-V thin film devices include light emitting diodes (LED) having a Group III-V thin film, photovoltaic solar cells having a Group III-V thin film, quantum well heterostructure devices having a Group III-V thin film, multiple quantum well heterostructure devices having a Group III-V thin film, and the like. For example, LEDs typically comprise a substrate (e.g., a silicon wafer), one or more AlN layers, and one or more GaN layers. In some embodiments, devices prepared include one or more gallium nitride thin film, indium gallium nitride thin film, aluminum nitride thin film, indium nitride thin film, aluminum gallium nitride thin film, or indium gallium aluminum nitride thin film. In some embodiments, the devices prepared include a layer comprising epitaxial layers of gallium nitride and indium gallium nitride. In some embodiments, the devices prepared include a layer comprising epitaxial layers of aluminum nitride, aluminum gallium nitride, gallium nitride, indium gallium nitride, or aluminum indium gallium nitride.

The systems and methods also have general applicability to materials such as metal nitrides, particularly transition metal nitrides (e.g., TiN, TaN, HfN), and Group IV insulators (e.g., SiN). Additionally the approach can be extended to oxide deposition (e.g., SiO₂, HfO₂, TiO₂, etc.), the preparation of oxynitride films (e.g., Si—O—N), and carbon containing films (e.g. Si—C—O—N). In some embodiments, devices are prepared including a layer comprising a transition metal oxide, a transition metal nitride or a transition metal oxynitride.

The systems and methods also have general applicability to materials such as diamond, graphene, and diamond-like carbon.

The systems and methods can also be extended to the use of hydrogen and/or inert gas plasmas to provide non-thermal energy to the growth front of the growing film. The use of inert plasmas can provide tailoring of the surface energy during the growth, texturing of the surface, control of the growth rate, affects on the growth temperature, and the impurity levels in the film. As an example, the chemically reactive species generated in a hydrogen plasma can be useful in scavenging the residual carbon from the decomposition of metal organic precursors off of the surface of the deposited film. This scavenging reduces the in-film carbon contamination which can be detrimental to the optical, electronic, or mechanical properties of the film.

Additional applications include research and development of devices such as sensors or photovoltaic devices utilizing II-VI technologies. In addition, chalcopyrite phase materials (Cu—In—Ga—Se) can be prepared using the methods and apparatuses of the present invention. Further, transition metal oxides and nitrides for use as dielectrics in microelectronic and optoelectronic devices can be prepared.

Low temperature growth of c-axis oriented AlN and/or AlN/AlGaN multilayers on Si has been achieved in a reactor as described above and in the Examples below by combining MOCVD deposition of Al from a trimethylaluminum precursor followed by nitridization using a nitrogen plasma. Subsequent layers comprising GaN or InGaN with suitable dopants can be deposited by MOCVD to form optoelectronic devices such as LEDs. The cluster tool arrangement can be advantageous to maximize manufacturing throughput by allowing each processing chamber to be optimized for maximum processing speed in depositing the respective layers. For example, the MOCVD/plasma processing chamber can be used for low-temperature deposition of AlN, and a conventional MOCVD processing chamber can be used to deposit the various semiconductor layers for a GaN LED. Additional layers can be deposited or processed by use of additional modules in a cluster tool, such as physical vapor deposition of electrode or dielectric layers, ovens for annealing, and the like.

### Advantages

The systems and methods of the present invention allow the formation of layers both by CVD processes involving the simultaneous provision of two or more precursor gases to a surface for reactive deposition, and by processes that combine CVD deposition and a sequential plasma treatment in a cyclic fashion. The cyclic deposition process, in which the gases used in the CVD deposition are separated from the gases in the plasma, eliminates problems associated with reactive CVD and PECVD. In particular, the present systems and methods reduce (1) dust formation due to the ionization of metal organic precursors and the interaction of metal-organic precursors with the reactive species in the plasma or second precursor gas, and (2) chamber wall coating due to the same gas phase interaction between metal-organic precursors with the reactive species in the plasma or precursor gas. The reduction in dust formation results in superior films with fewer particles and defects, an important aspect for microelectronics, photovoltaics, optoelectronics (e.g., LEDs) and optically transparent coatings. The reduction in chamber wall coating reduces the need for chamber cleaning periodic maintenance and chamber cleaning chemistries (which are often toxic and damaging to the chamber hardware and pumps).

In addition, some embodiments of the present invention provide improved methods for forming layers on substrates. In particular, wafer stress can result from treatment of substrates to deposit layers at high temperatures. Wafer bowing can result from lattice mismatch between substrate surface and layers formed thereon due to differences in thermal expansion. The inventive systems and methods described herein using plasmas in conjunction with chemical vapor deposition can ameliorate these stresses by providing effective layer deposition in the absence of high thermal activation required with conventional MOCVD. Plasma energy can provide nonthermal energy to aid in formation of layers, thereby reducing stresses due to high heat exposures. Thus, the inventive approaches provide greater ability to tailor the surface energy during the growth of a layer, to control the resulting texture of the surface, the growth rate, the growth temperature, and the impurity levels in the film.

### INCORPORATION BY REFERENCE

Methods and systems of embodiments of the invention may be combined with, or modified by, other systems and methods. For example, methods and systems of embodiments of the invention may be combined with, or modified by, methods and systems described in U.S. Pat. No. 6,305,314, U.S. Pat. No. 6,451,695, U.S. Pat. No. 6,015,590, U.S. Pat. No. 5,366,555, U.S. Pat. No. 5,916,365, U.S. Pat. No. 6,342,277, U.S. Pat. No. 6,197,683, U.S. Pat. No. 7,192,849, U.S. Pat. No. 7,537,950, U.S. Pat. No. 7,326,963, U.S. Pat. No. 7,491,626, U.S. Pat. No. 6,756,318, U.S. Pat. No. 6,001,173, U.S. Pat. No. 6,856,005, U.S. Pat. No. 6,869,641, U.S. Pat. No. 7,348,606, U.S. Pat. No. 6,878,593, U.S. Pat. No. 6,764,888, U.S. Pat. No. 6,690,042, U.S. Pat. No. 4,616,248, U.S. Pat. No. 4,614,961, U.S. Pat. No. 8,143,147, U.S. Patent Publication No. 2006/0021574, U.S. Patent Publication No. 2007/0141258, U.S. Patent Publication No. 2007/0186853, U.S. Patent Publication No. 2007/0215036, U.S. Patent Publication No. 2007/0218701, U.S. Patent Publication No. 2008/0173735, U.S. Patent Publication No. 2009/0090984, U.S. Patent Publication No. 2010/0210067, Patent Cooperation Treaty (“PCT”) Publication No. WO/2003/041141, PCT Publication No. WO/2006/034540 and PCT Publication No. WO/2010/091470, and PCT Publication No. WO/2010/092482, which are entirely incorporated herein by reference.

### EXAMPLES

### Example 1

### Preparation of AlN Layers

Si(111) wafers were prepared by a two-step cleaning process. The wafers were boiled in an aqueous solution of HCl and H₂O₂, rinsed and dried, then etched in 20% HF. AlN was grown on the Si wafers by first exposing the wafers to trimethylaluminum at a pressure of about 0.5 Torr and a wafer temperature of 700-900° C. About 0.5 ML of Al was formed on the surface which was then exposed to a N₂ plasma at 500 W. The plasma power was sufficient to generate active neutral species of nitrogen having the lowest excited state of molecular nitrogen (A³Σᵤ⁺). The exposure to excited species of N₂ was sufficient to produce a layer of aluminum nitride on the surface of the substrate.

In this example, the wafer was continuously rotating between the chemical vapor deposition environment and the plasma environment to provide alternating exposures to the environments. The net growth rate of AlN was 1.2 μm/hr, and a 0.62 μm film was deposited in about 30 min as measured by laser reflectometry. Subsequent analysis by X-ray diffraction (XRD) showed a single peak corresponding to the (0002) reflection from c-axis oriented AlN. The absence of other peaks indicated that the deposited film was hexagonal and c-axis oriented on the Si(111) surface. Atomic Force Microscopy (AFM) indicated that the surface roughness was about 8.5 nm (rms), and the typical column width was about 25 nm. XRD data for samples as a function of wafer temperature during deposition indicated that the crystalline quality (as measured by the width of the X-ray peak) generally improved with increasing temperature.

### Example 2

### Preparation of AlN/AlGaN Layers

AlN/AlGaN bilayers were deposited in the same apparatus by a similar process to that described in Example 1. A thin (100 nm) layer of AlN was first grown as described above followed by an AlGaN layer. The bilayer was produced in a continuous process by adding triethylgallium to the CVD environment after treatment for 340 seconds using only trimethylaluminum. The mole ratio of gallium to aluminum was 1:1. A total layer thickness of 0.68 μm was deposited at a rate of 1.7 μm/hr.

XRD analysis indicated that both the AlN layer and the AlGaN layer were hexagonal and c-axis oriented. The actual composition of the deposited layer was found to be AlₓGa₁₋ₓN, where x=0.4. Surface roughness measured by AFM was 7.9 nm (rms) and the typical column width was about 25 nm.

These results confirmed that high quality AlN and AlGaN films could be formed using the apparatuses and methods of the instant invention at low temperature (compared to the more than 1200° C. required for direct MOCVD processes).

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A deposition system comprising
a plurality of processing chambers;
a first substrate transport system capable of loading substrates sequentially into the plurality of processing chambers;
a first processing chamber of the plurality of processing chambers comprising
a first processing environment,
a second processing environment,
a second substrate transport system capable of positioning a substrate for sequential processing in each processing environment, and
a gas control system capable of maintaining isolation of each processing environment;
wherein the first processing environment is operable to form a layer by contacting the substrate with one or more precursor gases, and
wherein the second processing environment is operable to contact the substrate with a plasma; and
a second processing chamber of the plurality of processing chambers comprising
a gas emission system capable of providing a plurality of precursor gases for deposition onto a substrate,
wherein the second processing chamber is operable to deposit one or more layers on the substrate by reaction of precursor gases on the substrate.

2. The system of claim 1, wherein the second substrate transport system is a planetary wafer transport system comprising
one or more substrate supports disposed on a motorized platform, and
a controller for controlling the time spent in each processing environment and the speed at which the substrate moves between processing environments,
wherein the motorized platform rotates about a central axis disposed approximately equidistant from each processing environment, and
wherein the one or more substrate supports are capable of independently controlling the temperature of the substrate.

3. The system of claim 2, wherein each substrate support further comprises a motor for providing rotational motion to the substrate.

4. The system of claim 2, wherein each substrate support further comprises a heater.

5. The system of claim 1, wherein the gas control system provides for the introduction and evacuation of gases such that gases from one processing environment are not reactive in another processing environment.

6. The system of claim 1, wherein the first processing chamber further comprises at least two processing environments operable to form a layer by contacting the substrate with one or more precursor gases.

7. The system of claim 1, wherein the first processing chamber further comprises at least two processing environments operable to contact the substrate with a plasma.

8. The system of claim 1, wherein the first processing chamber further comprises a metrology environment.

9. A method of depositing layers on a substrate comprising
depositing at least one layer on a substrate by a first method in a first processing chamber,
wherein the first processing chamber comprises a first processing environment, a second processing environment, a substrate transport system operable to position a substrate for sequential processing in each environment, and a gas control system operable to maintain isolation of each environment;
wherein the first method comprises
forming a first layer on the substrate in the first processing environment by contacting the substrate with one or more precursor gases,
contacting the substrate with plasma in the second processing environment, and
repeating the forming and contacting steps until a layer of desired thickness is formed;
wherein the first processing environment is operable to perform chemical vapor deposition; and
wherein the second processing environment is operable to contact the substrate with a plasma; and
depositing at least one layer on the substrate by a second method in a second processing chamber;
wherein the second method comprises forming a second layer on the substrate by contacting the substrate with a plurality of precursor gases in the second processing chamber.

10. The method of claim 9, wherein the contacting the substrate with plasma in a plasma processing environment is effective to deposit atoms from the plasma onto the substrate.

11. The method of claim 9, wherein the contacting the substrate with plasma in a plasma processing environment is effective to treat the surface of the substrate or a layer disposed on the substrate.

12. The method of claim 9, wherein the plasma is a reactive plasma comprising one or more of a halogen, oxygen, water, nitrogen, hydrogen, ammonia, hydrazine, methane, ethane, hydrogen selenide, hydrogen sulfide or hydrogen chloride.

13. The method of claim 9, wherein the plasma is an inert plasma comprising one or more of argon, krypton, helium, neon, or xenon.

14. The method of claim 9, wherein the plasma is a neutrals plasma.

15. A Group III-V, Group II-VI, or Group IV thin film formed according to the method of claim 9.

16. A light emitting diode (LED) having a Group III-V thin film formed according to the method of claim 15.

17. The method of claim 9, wherein the substrate is moved between the processing chambers utilizing a substrate transport system such that the substrate does not come into contact with gases outside the processing chambers.

18. The method of claim 9, wherein the layers on a substrate comprise:
at least one layer comprising AlN deposited by the first method, and
at least one layer comprising AlGaN, undoped GaN, n-type doped GaN, or InGaN deposited by the second method.

19. The method of claim 9, wherein the layers on a substrate comprise:
at least one layer comprising AlN deposited by the first method,
at least one layer comprising undoped GaN deposited by the second method, and
at least one layer comprising InGaN deposited by the first method.

20. The method of claim 9, wherein the layers on a substrate comprise:
at least one layer comprising AlN deposited by the first method,
at least one layer comprising undoped GaN deposited by the first method, and
at least one layer comprising InGaN deposited by the second method.
